(19) United States
(12) Patent Application Publication
(10) Pub. No.: US 2009/0180640 A1
(43) Pub. Date: Jul. 16, 2009

(54) HEADPHONE AMPLIFIER CIRCUIT

(75) Inventor: Hirofumi OGAWA, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/337,936

(22) Filed: Dec. 18, 2008

(30) Foreign Application Priority Data
Jan. 10, 2008 (JP) 2008-003289

(51) Int. Cl. H04R 1/00; H03F 99/00

(52) U.S. Cl. 381/74; 381/120

(57) ABSTRACT

The present invention provides a headphone amplifier circuit capable of canceling the influence of a parasitic resistance developed thereinside thereby to improve channel separation and increase output amplitude thereof. When audio signals respectively inputted to minus input terminals via resistors are amplified by inverting amplifiers each having a negative feedback circuit including a resistor and thereafter applied to input ends of left and right headphones, and the voltage of a preset potential is applied to each of output terminals of the headphones by an amplifier, a center output terminal of the amplifier and plus input terminals of the inverting amplifiers are connected to one another via resistors, and the plus input terminals of the inverting amplifiers are grounded via resistors respectively.

### BACKGROUND OF THE INVENTION

The present invention relates to a headphone amplifier circuit.

In a headphone amplifier circuit, sound or audio signals for right and left channels have heretofore been amplified by amplifiers and outputted the amplified to headphones (loads), respectively. In the present headphone amplifier circuit, there is a case in which noise is generated depending upon dc potentials at both ends of the left and right loads. A circuit that has cut dc components by providing coupling capacitors at output ends of left and right amplifiers has also been proposed.

There has also been proposed a circuit in which an amplifier whose output end is connected between left and right channels is provided as a center amplifier to equalize dc-potentials at both ends of left and right channel loads, thereby realizing the cutting of noise caused by dc components at low current consumption without providing coupling capacitors at output ends of left and right amplifiers (refer to, for example, patent documents 1 through 3 (Japanese Utility Model Application Laid-Open No. Hei 06 (1994)-062622, Japanese Patent Laid-Open No. Hei 08 (1996)-065068 and Japanese Patent Laid-Open No. 2003-047086)).

One example of a basic configuration of a headphone amplifier circuit 100 of a conventional center amplifier system is shown in FIG. 2. As shown in the same figure, the headphone amplifier circuit 100 includes a left output terminal 116, a center output terminal 118 and a right output terminal 120. A left channel headphone 112 is connected to the left output terminal 116 and the center output terminal 118, and a right channel headphone 114 is connected to the right output terminal 120 and the center output terminal 118, respectively.

As shown in the same figure, the headphone amplifier circuit 100 includes an inverting amplifier 122 for amplifying a left audio signal Lch, an inverting amplifier 126 for amplifying a right audio channel Rch and an amplifier 124 that functions as a voltage follower.

As shown in the same figure, the inverting amplifier 122 has a minus input terminal to which the audio signal Lch is inputted via a resistor R11 and a plus input terminal to which a reference potential C is inputted. The output of the inverting amplifier 122 is connected via a resistor R12 and configured as negative feedback circuit.

The inverting amplifier 126 has a minus input terminal to which the audio signal Rch is inputted via a resistor R11 and a plus input terminal to which the reference potential C is inputted. The output of the inverting amplifier 126 is connected via a resistor R12 and configured as a negative feedback circuit.

In the headphone amplifier circuit 100 configured in this way, a voltage VL at the left output terminal 116 is expressed in the following equation (1) and a voltage VR at the right output terminal 120 is expressed in the following equation (2), respectively:

$$\begin{matrix}VL = - \frac{R 12}{R 11} \times Lch & ( 1 ) \\ VR = - \frac{R 12}{R 11} \times Rch & ( 2 )\end{matrix}$$

Assuming that the parasitic resistance lying inside a semiconductor used for the headphone amplifier circuit 100 is Rc and the impedance of each of the headphones 112 and 114 is Rhp, a voltage Vc at the center output terminal 118 is expressed in the following equation (3):

$$Vc = \frac{Rc}{Rhp + 2 Rc} \times ( VL + VR ) \qquad ( 3 )$$

Since the output VoL of the left channel headphone 112 becomes VL−Vc, the output VoL is expressed in the following equation (4):

$$VoL = \frac{Rhp + Rc}{Rhp + 2 Rc} \times ( - \frac{R 12}{R 11} \times Lch ) - \frac{Rc}{Rhp + 2 Rc} \times ( - \frac{R 12}{R 11} \times Rch ) \qquad ( 4 )$$

Since the output VoR of the right channel headphone 114 becomes VoR=VR−Vc in a manner similar to the output VoL of the left channel headphone 112, the output VoR is expressed in the following equation (5):

$$VoR = \frac{Rhp + Rc}{Rhp + 2 Rc} \times ( - \frac{R 12}{R 11} \times Rch ) - \frac{Rc}{Rhp + 2 Rc} \times ( - \frac{R 12}{R 11} \times Lch ) \qquad ( 5 )$$

A problem however arises in that when the value of Rc is large, the influence of an input signal of another channel on the left channel output VoL and the right channel output VoR becomes innegligible, and channel separation is degraded.

### SUMMARY OF THE INVENTION

The present invention has been made to solve the above problem. It is an object of the present invention to provide a headphone amplifier circuit capable of canceling the influence of a parasitic resistance developed thereinside thereby to improve channel separation and increase output amplitude thereof.

According to one aspect of the present invention, for attaining the above object, there is provided a headphone amplifier circuit comprising voltage amplifying means for amplifying a voltage of a preset potential applied to each of output ends of two loads driven by audio signals; and two audio signal amplifying means respectively having first input terminals connected with negative feedback circuits which are respectively inputted with the two audio signals to be applied to input ends of the two loads via resistors each having a first resistance value and which have resistors each having a second resistance value, and having second input terminals which are connected to an output end of the voltage amplifying means via means for adjusting a voltage level and grounded via resistors each having a third resistance value, the audio signal amplifying means amplifying the inputted audio signals. The first resistance value, the second resistance value, the third resistance value and the resistance value of the adjusting means satisfy the following equation where the first resistance value is R1, the second resistance value is R2, the third resistance value is R3 and the resistance value of the adjusting means is R4:

$$( 1 + \frac{R 2}{R 1} ) \times ( \frac{R 3}{R 3 + R 4} ) = 1$$

As described above, the present invention has an excellent advantageous effect that the influence of parasitic resistance developed thereinside is canceled, thereby making it possible to improve channel separation and increase output amplitude thereof.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. is a block diagram schematically showing a configuration of a headphone amplifier circuit according to an embodiment; and

FIG. 2 is a block diagram schematically showing a configuration of a conventional headphone amplifier circuit.

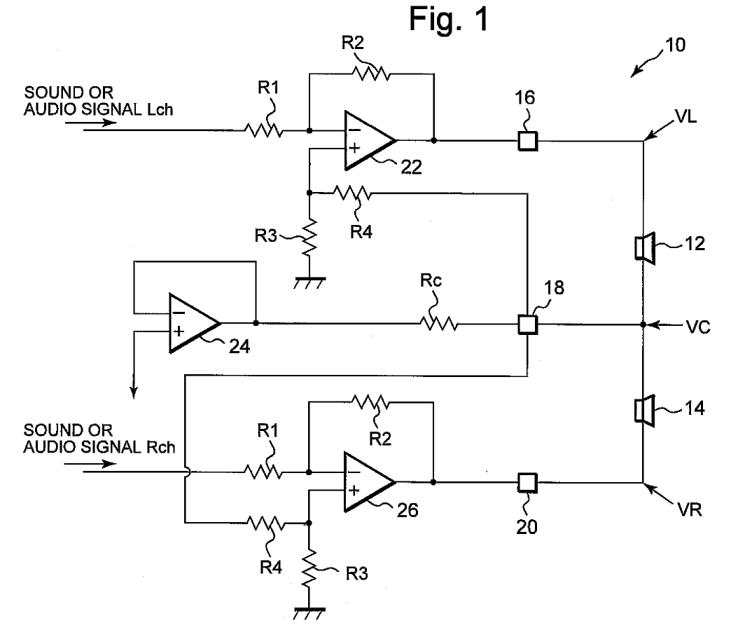

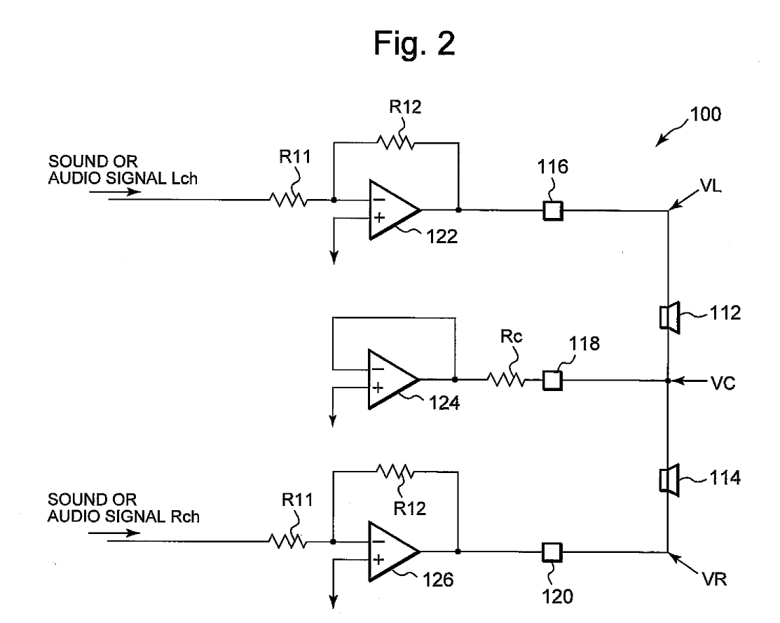

### DETAILED DESCRIPTION OF THE PREFERRED EMBODIMENTS

A preferred embodiment of the present invention will hereinafter be described in detail with reference to the accompanying drawing.

FIG. 1 schematically shows a configuration of a headphone amplifier circuit 10 according to the present embodiment. As shown in the same figure, the headphone amplifier circuit 10 includes a left output terminal 16, a center output terminal 18 and a right output terminal 20. A left channel headphone 12 corresponding to a load of the headphone amplifier circuit 10 is connected to the left output-terminal 16 and the center output terminal 18, and a right channel headphone 14 is connected to the right output terminal 20 and the center output terminal 18, respectively.

As shown in the same figure, the headphone amplifier circuit 10 includes an inverting amplifier 22 for amplifying a left audio signal Lch, an inverting amplifier 26 for amplifying a right audio channel Rch and an amplifier 24 that functions as a voltage follower.

As shown in the same figure, the inverting amplifier 22 has a minus input terminal to which the audio signal Lch is inputted via a resistor R1 and which is connected to an output end thereof via a resistor R2. The inverting amplifier 22 is configured as a negative feedback circuit. A plus input terminal of the inverting amplifier 22 is connected to the center output terminal via a resistor R4 and grounded via a resistor R3.

The inverting amplifier 26 has a minus input terminal to which the audio signal Rch is inputted via a resistor R1 and which is connected to an output end thereof. The inverting amplifier 26 is configured as a negative feedback circuit. A plus input terminal of the inverting circuit 26 is connected to the center output terminal 18 via a resistor R4 and grounded via a resistor R3.

Assuming that the voltage of the center output terminal 18 is Vc in the so-configured headphone amplifier circuit 10, a voltage VL applied to the left output terminal 16 is expressed in the following equation (6), and a voltage VR applied to the right output terminal 20 is expressed in the following equation (7), respectively.

$$\begin{matrix}VL = - \frac{R 2}{R 1} \times Lch + ( 1 + \frac{R 2}{R 1} ) \times ( \frac{R 3}{R 3 + R 4} ) \times Vc & ( 6 ) \\ VR = - \frac{R 2}{R 1} \times Rch + ( 1 + \frac{R 2}{R 1} ) \times ( \frac{R 3}{R 3 + R 4} ) \times Vc & ( 7 )\end{matrix}$$

When the resistance values of the resistors R1, R2, R3 and R4 are selected so as to satisfy the following equation (8) here, the above equations (6) and (7) are given by the following equations (9) and (10) respectively:

$$\begin{matrix}( 1 + \frac{R 2}{R 1} ) \times ( \frac{R 3}{R 3 + R 4} ) = 1 & ( 8 ) \\ VL = - \frac{R 2}{R 1} \times Lch + Vc & ( 9 ) \\ VR = - \frac{R 2}{R 1} \times Rch + Vc & ( 10 )\end{matrix}$$

Incidentally, as the values of R1, R2, R3 and R4 that satisfy the above equation (8), there may be mentioned, for example, values that satisfy R2=R1 and R3=R4. Since the resistance values of R1, R2, R3 and R3 are generally a few kΩ or more, through current that flows through R3 and R4 from the center output terminal 18 presents no problem.

In this case, the output amplitude can be made large by Vc than conventional (refer to the equations (1) and (2)).

Since the output VoL of the left channel headphone 12 becomes VL−Cc, it is expressed in the following equation (11):

$$VoL = - \frac{R 2}{R 1} \times Lch \qquad ( 11 )$$

Since the output VoR of the right channel headphone 14 also becomes VoR=VR−Vc in a manner similar to the output VoL of the left channel headphone 12, it is expressed in the following equation (12):

$$VoR = - \frac{R 2}{R 1} \times Rch \qquad ( 12 )$$

As expressed in these equations (11) and (12), the output VoL of the left channel headphone 12 and the output VoR of the right channel headphone 14 are not affected by the input signals to the mutual channels.

According to the present embodiment as described above, when the audio signals Lch and Rch respectively inputted to the minus input terminals via the resistors R1 are respectively amplified by the inverting amplifiers 22 and 26 each including the negative feedback circuit having the resistor R2, followed by being inputted to their corresponding input ends of the left and right headphones 12 and 14, and when the voltage of a present potential is applied to each of the output ends of the headphones 12 and 14 by the amplifier 24, the center output terminal 18 of the amplifier 24 and the plus input terminals of the inverting amplifiers 22 and 26 are connected to one another via the resistors R4, and the plus input terminals of the inverting amplifiers 22 and 26 are grounded via the resistors R3 thereby to satisfy the equation (8) referred to above. Thus, the cancellation of the influence of parasitic resistance lying inside the headphone amplifier circuit makes it possible to improve channel separation and increase output amplitude.

Incidentally, the configuration of the headphone amplifier circuit 10 and the flow of various processes thereof both described in the present embodiment are illustrated by way of example. It is needless to say that they can suitably be changed within the scope not departing from the gist of the present invention.

Although the present embodiment has described the form in which the present invention is applied to the analog amplifier circuit, for example, the present invention can be applied even to a D-class amplifier circuit.

What is claimed is:

1. A headphone amplifier circuit comprising:
voltage amplifying means for amplifying a voltage of a preset potential applied to each of output ends of two loads driven by audio signals; and
two audio signal amplifying means respectively having first input terminals connected with negative feedback circuits which are respectively inputted with the two audio signals to be applied to input ends of the two loads via resistors each having a first resistance value and which have resistors each having a second resistance value, and having second input terminals which are connected to an output end of the voltage amplifying means via means for adjusting a voltage level and grounded via resistors each having a third resistance value, said audio signal amplifying means amplifying the inputted audio signals.

2. The headphone amplifier circuit according to claim 1, wherein the first resistance value, the second resistance value, the third resistance value and the resistance value of the adjusting means satisfy the following equation where the first resistance value is R1, the second resistance value is R2, the third resistance value is R3 and the resistance value of the adjusting means is R4:
$$( 1 + \frac{R 2}{R 1} ) \times ( \frac{R 3}{R 3 + R 4} ) = 1$$
